(19) United States
(12) Patent Application Publication
(10) Pub. No.: US 2008/0224170 A1
(43) Pub. Date: Sep. 18, 2008

(54) Semiconductor wafer, light emitting diode print head, image forming apparatus, and method of producing semiconductor device

(75) Inventors: Mitsuhiko Ogihara, Tokyo (JP); Tomoki Igari, Tokyo (JP); Hiroyuki Fujiwara, Tokyo (JP); Tomohiko Sagimori, Tokyo (JP); Takahito Suzuki, Tokyo (JP); Hironori Furuta, Tokyo (JP); Yusuke Nakai, Tokyo (JP)

Correspondence Address: KUBOTERA & ASSOCIATES, LLC, Suite 202, 200 Daingerfield Road, Alexandria, VA, 22314, US

(73) Assignee: Oki Data Corporation

(21) Appl. No.: 12/076,052

(22) Filed: Mar. 13, 2008

(30) Foreign Application Priority Data
Mar. 16, 2007 (JP) 2007-068270

(51) Int. Cl. H01L 33/00; H01L 21/00

(52) U.S. Cl. 257/102; 438/45; 257/E21.001; 257/E33.001

(57) ABSTRACT

A nitride semiconductor wafer includes a substrate; a nitride compound semiconductor layer formed on the substrate; and an AlₓGa₁₋ₓAs layer (x≧0.6) formed between the substrate and the nitride semiconductor layer. The nitride compound semiconductor layer is formed of a nitride compound in a group III to a group V.

### BACKGROUND OF THE INVENTION AND RELATED ART STATEMENT

The present invention relates to a semiconductor wafer, a light emitting diode (LED) print head; and an image forming apparatus including the light emitting diode (LED) print head. The present invention also relates to a method of producing a semiconductor device. More specifically, the present invention relates to a nitride semiconductor wafer, and a method of producing a thin film semiconductor device using the nitride semiconductor wafer.

A conventional light source includes a semiconductor light emitting element such as an LED (Light Emitting Diode). Patent Reference has disclosed a semiconductor light emitting element having a laminated structure. The laminated structure includes a layer formed of a nitride semiconductor through an epitaxial growth.
Patent Reference: Japanese Patent Publication No. 05-41541

FIG. 2 is a view showing the laminated structure of the conventional nitride semiconductor. As shown in FIG. 2, a surface nitride film 102 and an AIN buffer layer 103 are sequentially formed on a sapphire substrate 101. A GaN layer 104 and a GaN light emitting layer 105 as nitride semiconductor layers are formed on the AIN buffer layer 103. Electrodes are formed on the GaN layer 104 and the GaN light emitting layer 105, respectively. With the laminated structure shown in FIG. 2, it is possible to obtain the semiconductor light emitting element formed on the sapphire substrate 101.

In the conventional semiconductor light emitting element, the sapphire substrate 101 is formed of a relatively expensive material, thereby increasing a cost. Further, it is difficult to machine the sapphire substrate 101. Accordingly, it is difficult to scribe the conventional semiconductor light emitting element into individual pieces.

To this end, a nitride semiconductor layer may be exfoliated from the sapphire substrate 101. In general, a semiconductor layer is exfoliated from a substrate through a laser lift-off method. In the laser lift-off method, laser light is irradiated on a nitride semiconductor layer from a side of a substrate, i.e., exfoliated from the sapphire substrate 101, so that the nitride semiconductor layer is exfoliated from the sapphire substrate 101.

In the laser lift-off method, it is necessary to accurately scan laser light on an exfoliation surface to exfoliate the nitride semiconductor layer from the sapphire substrate 101. Accordingly, it is difficult to exfoliate the nitride semiconductor layer over a large area. Further, it is possible to apply the laser lift-off method only to a substrate transparent with respect to laser light such as the sapphire substrate 101, i.e., the expensive substrate. Accordingly, it is difficult to apply the laser lift-off method to a mass production line.

In view of the problems described above, an object of the present invention is to provide a nitride semiconductor wafer, and a method of producing a thin film semiconductor device using the nitride semiconductor wafer. In the present invention, a nitride semiconductor layer is formed on a non-transparent substrate, and the nitride semiconductor layer is exfoliated from the non-transparent substrate through a chemical etching process. Accordingly, it is possible to reuse the non-transparent substrate.

Further objects and advantages of the invention will be apparent from the following description of the invention.

### SUMMARY OF THE INVENTION

In order to attain the objects described above, according to the present invention, a nitride semiconductor wafer includes a substrate; a nitride compound semiconductor layer formed on the substrate; and an AlₓGa₁₋ₓAs layer (x≧0.6) formed between the substrate and the nitride semiconductor layer. The nitride compound semiconductor layer is formed of a nitride compound in a group III to a group V.

In the nitride semiconductor wafer of the present invention, the nitride semiconductor layer is formed on the non-transparent substrate, and the nitride semiconductor layer is exfoliated from the non-transparent substrate through a chemical etching process. Accordingly, it is possible to reuse the non-transparent substrate.

### BRIEF DESCRIPTION OF THE DRAWINGS

FIG. 1 is a schematic sectional view showing a laminated structure of a nitride semiconductor wafer according to a first embodiment of the present invention;

FIG. 2 is a schematic sectional view showing a laminated structure of a conventional nitride semiconductor;

FIG. 3 is a schematic view No. 1 showing a process of producing a thin film semiconductor device according to the first embodiment of the present invention;

FIG. 4 is a schematic view No. 2 showing the process of producing the thin film semiconductor device according to the first embodiment of the present invention;

FIG. 5 is a schematic view No. 3 showing the process of producing the thin film semiconductor device according to the first embodiment of the present invention;

FIG. 6 is a schematic view No. 4 showing the process of producing the thin film semiconductor device according to the first embodiment of the present invention;

FIG. 7 is a schematic view No. 1 showing a process of producing an LED (Light Emitting Diode) array using the thin film semiconductor device according to the first embodiment of the present invention;

FIG. 8 is a schematic view No. 2 showing the process of producing the LED (Light Emitting Diode) array using the thin film semiconductor device according to the first embodiment of the present invention;

FIG. 9 is a schematic view No. 3 showing the process of producing the LED (Light Emitting Diode) array using the thin film semiconductor device according to the first embodiment of the present invention;

FIG. 10 is a schematic view No. 4 showing the process of producing the LED (Light Emitting Diode) array using the thin film semiconductor device according to the first embodiment of the present invention;

FIG. 11 is a schematic view No. 5 showing the process of producing the LED (Light Emitting Diode) array using the thin film semiconductor device according to the first embodiment of the present invention;

FIG. 12 is a schematic perspective view showing an LED-drive IC (Integrated Circuit) combination chip according to the first embodiment of the present invention;

FIG. 13 is a schematic sectional view an LED print head formed of the semiconductor device according to the first embodiment of the present invention;

FIG. 14 is a schematic plan view showing an LED unit in the LED print head according to the first embodiment of the present invention;

FIG. 15 is a schematic view showing an image forming apparatus including the LED print head shown in FIG. 13 according to the first embodiment of the present invention;

FIG. 16 is a schematic sectional view showing a laminated structure of a nitride semiconductor wafer according to a second embodiment of the present invention;

FIG. 17 is a schematic sectional view showing a laminated structure of a nitride semiconductor wafer according to a third embodiment of the present invention;

FIG. 18 is a schematic sectional view showing a first modified example of the laminated structure of the nitride semiconductor wafer according to the third embodiment of the present invention;

FIG. 19 is a schematic sectional view showing a second modified example of the laminated structure of the nitride semiconductor wafer according to the third embodiment of the present invention;

FIG. 20 is a schematic sectional view showing a laminated structure of a nitride semiconductor wafer according to the fourth embodiment of the present invention;

FIG. 21 is a schematic view No. 1 showing a process of producing a thin film semiconductor device according to the fourth embodiment of the present invention; and

FIG. 22 is a schematic view No. 2 showing the process of producing the thin film semiconductor device according to the fourth embodiment of the present invention.

### DETAILED DESCRIPTION OF THE PREFERRED EMBODIMENTS

Hereunder, embodiments of the present invention will be explained with reference to the accompanying drawings.

### First Embodiment

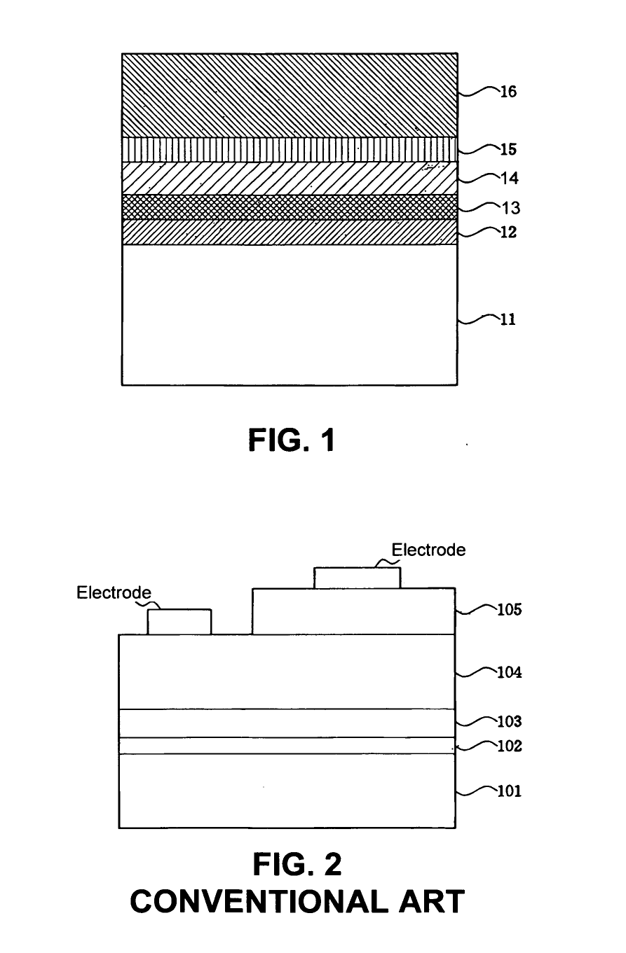

A first embodiment of the present invention will be explained. FIG. 1 is a schematic sectional view showing a laminated structure of a nitride semiconductor wafer according to the first embodiment of the present invention.

As shown in FIG. 1, a GaAs buffer layer 12 as a buffer layer is formed on a GaAs substrate 11 as a non-transparent substrate of a nitride semiconductor device. An AlAs layer 13 as a sacrifice layer is formed on the GaAs buffer layer 12. The AlAs layer 13 is provided for exfoliating a nitride compound semiconductor layer from the GaAs substrate 11, and is formed of a material easy to etch with respect to an exfoliation etchant (described later).

In the embodiment, a GaAs layer 14 as a compound semiconductor layer is formed on the AlAs layer 13. An AlN buffer layer 15 as a buffer layer is formed on the GaSa layer 14. A GaN layer 16 as a nitride semiconductor layer of group III to V is formed on the AlN layer 15. Each of the GaAs buffer layer 12, the AlAs layer 13, the GaAs layer 14, the AlN buffer layer 15, and the GaN layer 16 may be formed with an organic metal chemical vapor deposition (MOCVD) method or a molecular beam epitaxy (MBE) method.

In the embodiment, the GaAs buffer layer 12, the AlAs layer 13, and the GaAs layer 14 are sequentially formed on the GaAs substrate 11 at a growth temperature of, for example, 600° C. to 750° C. Afterward, the AlN buffer layer 15 is grown at a low growth temperature of, for example, 400° C. to 600° C. Then, the GaN layer 16 is grown at a growth temperature of, for example, 800° C. to 1,100° C. under an environment of hydrogen gas or a mixture gas of nitrogen and ammonium.

A method of producing the thin film semiconductor device through exfoliating the GaN layer 16 from the GaAs substrate 11 will be explained next.

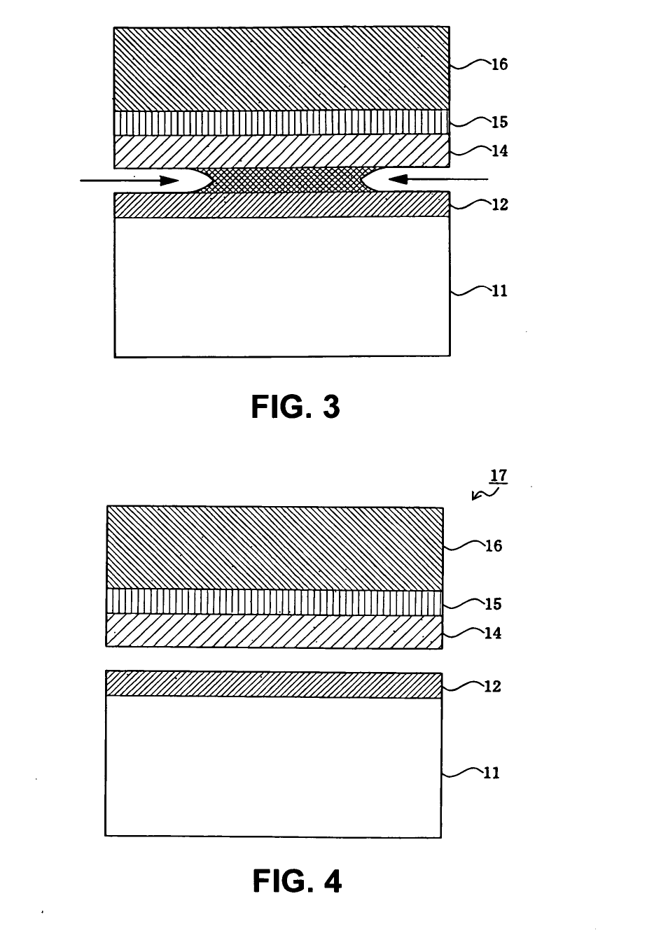

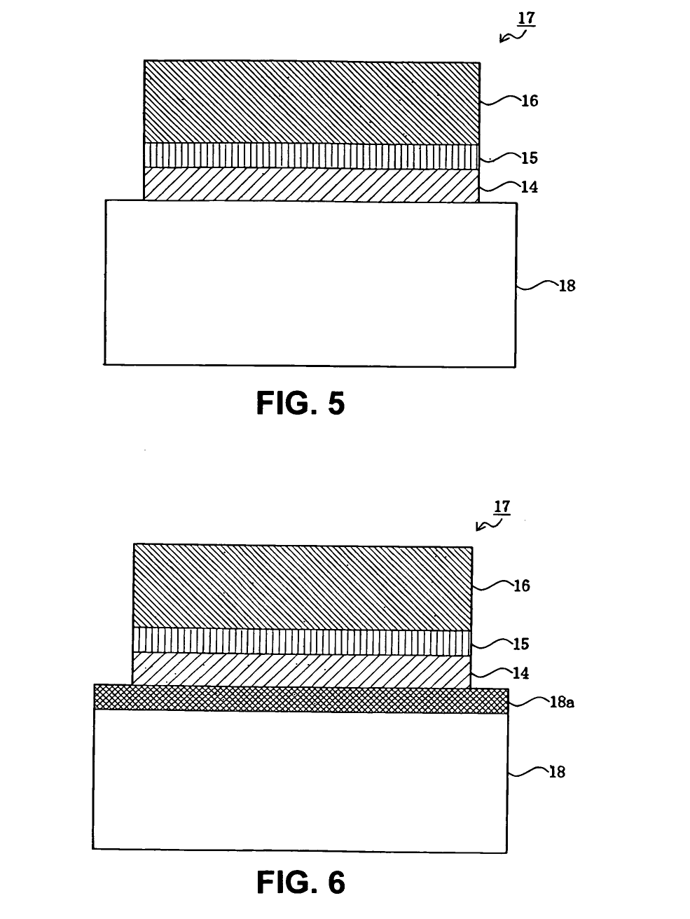

FIG. 3 is a schematic view No. 1 showing a process of producing the thin film semiconductor device according to the first embodiment of the present invention. FIG. 4 is a schematic view No. 2 showing the process of producing the thin film semiconductor device according to the first embodiment of the present invention. FIG. 5 is a schematic view No. 3 showing the process of producing the thin film semiconductor device according to the first embodiment of the present invention. FIG. 6 is a schematic view No. 4 showing the process of producing the thin film semiconductor device according to the first embodiment of the present invention.

In the embodiment, the GaAs buffer layer 12, the AlAs layer 13, and the GaAs layer 14 formed on the GaAs substrate 11 are epitaxial layers lattice-matched with respect to the GaAs substrate 11. Further, the AlN buffer layer 15 formed on the GaAs layer 14 functions as the buffer layer for controlling the GaN layer 16 and the layers thereabove to have an appropriate crystal structure.

In the embodiment, the AlAs layer 13 is selectively etched with respect to the GaAs layer 14, the AlN buffer layer 15, and the GaN layer 16. Accordingly, the GaAs layer 14, the AlN buffer layer 15, and the GaN layer 16 are selectively exfoliated. As shown in FIG. 3, it is possible to selectively etch the AlAs layer 13 using an acid such as hydrofluoric acid as the exfoliation etchant.

Note that the AlN buffer layer 15 also contains Al. However, the GaN layer 16 above the AlN buffer layer 15 is grown at a high temperature, so that the AlN buffer layer 15 has a high degree of crystallinity. Accordingly, it is difficult to etch the AlN buffer layer 15 using an acid such as hydrofluoric acid as the exfoliation etchant.

As shown in FIG. 4, when the AlAs layer 13 is selectively etched, the GaAs layer 14, the AlN buffer layer 15, and the GaN layer 16 are exfoliated and separated from the GaAs substrate 11 to obtain a semiconductor thin film layer 17.

In this case, it is possible to obtain a relatively large etching ratio, for example, about 10⁷, between the AlAs layer 13 and the GaAs layer 14 with respect to the etchant. Accordingly, after the AlAs layer 13 is etched and removed, it is possible to make a surface of the GaAs layer 14, i.e., an exfoliation surface of the semiconductor thin film layer 17, smooth. It is preferred that a roughness of the surface is less than at least 5 nm, more preferably, less than 2 nm. The roughness of the surface is measured as an average surface roughness of a specific area with an atomic force microscopy (AFM) in an area of, for example, 5 μm square to 25 μm square.

As shown in FIG. 5, after the semiconductor thin film layer 17 is exfoliated and separated from the GaAs substrate 11, it is possible to bond the semiconductor thin film layer 17 to a substrate 18, i.e., another substrate different from the GaAs substrate 11.

In the embodiment, as shown in FIG. 6, a film 18a formed of a material different from that of the substrate 18 may be disposed on a surface of the substrate. The film 18a is formed of a material different from that of the substrate 18 as an insulation film or a conductive film.

As described above, in the embodiment, the AlAs layer 13 is formed on the GaAs substrate 11 to be selectively etched with respect to the GaAs substrate 11. Further, the GaN layer 16 is formed on the AlAs layer 13 as the nitride compound semiconductor layer, thereby constituting an epitaxial layer structure.

Accordingly, it is possible to separate the semiconductor thin film layer 17 including the AlN buffer layer 15 from the GaAs substrate 11 without etching and removing the GaAs substrate 11. Further, the GaAs layer 14 is formed on the AlAs layer 13. Accordingly, it is possible to obtain the smooth surface of the semiconductor thin film layer 17 as the exfoliation surface.

In the embodiment, the AlAs layer 13 is provided as the exfoliation layer, and a layer formed of a material other than AlAs such as AlₓGa₁₋ₓAs (x≧0.6) may be formed as the exfoliation layer instead. Further, the AlN buffer layer 15 may be replaced with a nitride AlAs layer or nitride GaAs layer.

In the embodiment, an AlGaN layer or a super lattice layer of AlN/GaN may be formed on the AlN buffer layer 15. Further, the GaN layer 16 may be replaced with another layer, for example, an n-GaN layer, a quantum well structure layer of InGaN/GaN, a p-AlGaN layer, or a p-GaN layer.

A method of producing an LED (Light Emitting Diode) array using the thin film semiconductor device will be explained next.

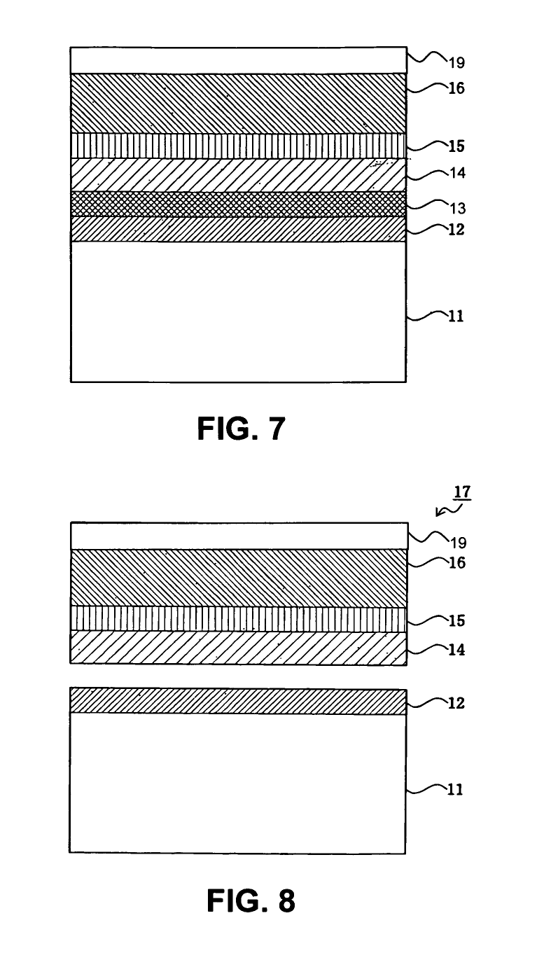

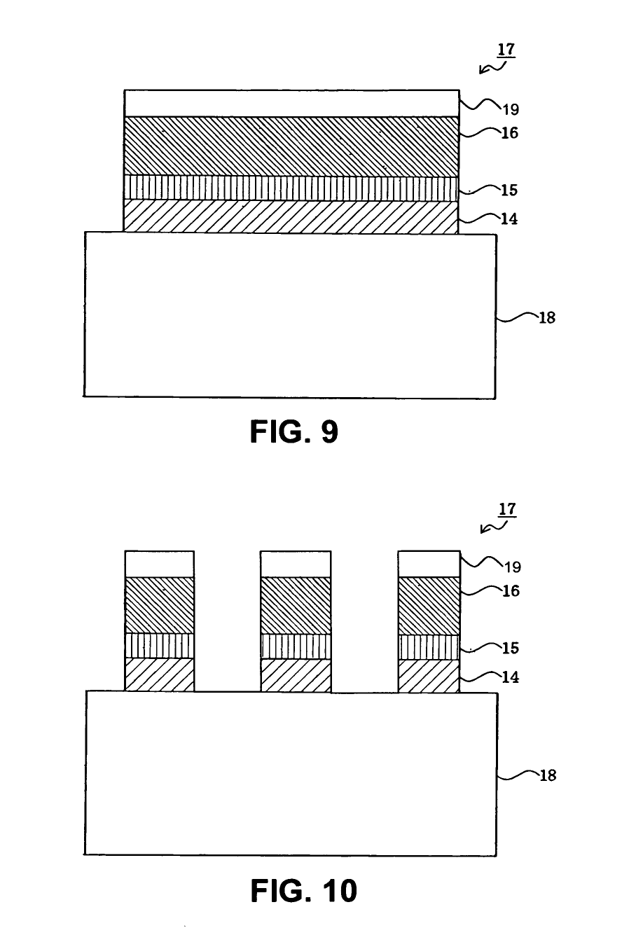

FIG. 7 is a schematic view No. 1 showing a process of producing an LED (Light Emitting Diode) array using the thin film semiconductor device according to the first embodiment of the present invention. FIG. 8 is a schematic view No. 2 showing the process of producing the LED (Light Emitting Diode) array using the thin film semiconductor device according to the first embodiment of the present invention. FIG. 9 is a schematic view No. 3 showing the process of producing the LED (Light Emitting Diode) array using the thin film semiconductor device according to the first embodiment of the present invention.

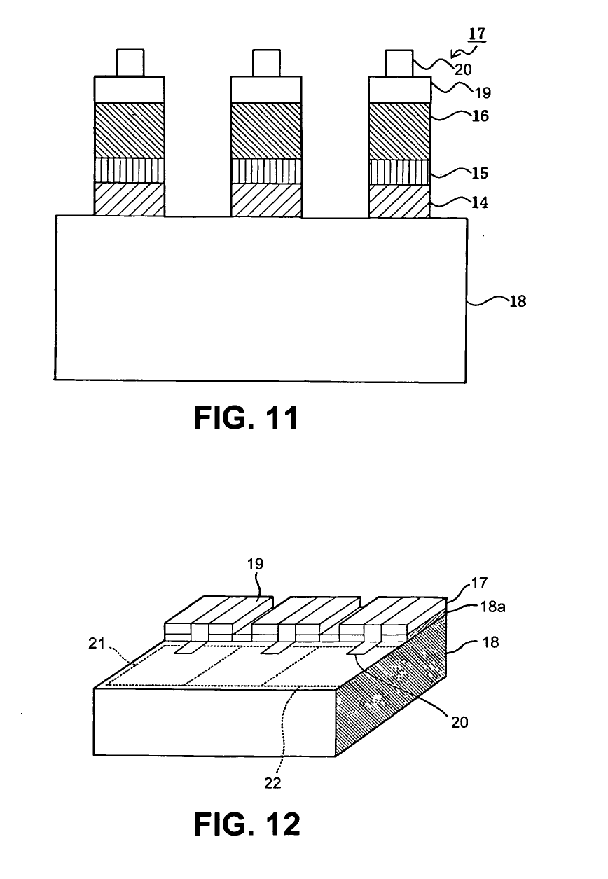

Further, FIG. 10 is a schematic view No. 4 showing the process of producing the LED (Light Emitting Diode) array using the thin film semiconductor device according to the first embodiment of the present invention. FIG. 11 is a schematic view No. 5 showing the process of producing the LED (Light Emitting Diode) array using the thin film semiconductor device according to the first embodiment of the present invention.

First, the nitride semiconductor wafer is prepared. As shown in FIG. 1, the nitride semiconductor wafer includes the GaAs buffer layer 12, the AlAs layer 13, and the GaAs layer 14 sequentially formed on the GaAs substrate 11. Further, the AlN buffer layer 15 formed on the GaAs layer 14 functions as the buffer layer for controlling the GaN layer 16 thereabove to have an appropriate crystal structure.

In the next step, as shown in FIG. 7, an impurity is diffused into the GaN layer 16 from above to form a diffused layer 19.

In the next step, as shown in FIG. 8, the AlAs layer 13 is selectively etched with respect to the GaAs layer 14, the AlN buffer layer 15, the GaN layer 16, and the diffused layer 19. Accordingly, the GaAs layer 14, the AlN buffer layer 15, the GaN layer 16, and the diffused layer 19 are selectively exfoliated. When the AlAs layer 13 is selectively etched, the GaAs layer 14, the AlN buffer layer 15, the GaN layer 16, and the diffused layer 19 are exfoliated and separated from the GaAs buffer layer 12 and the GaAs substrate 11.

In the next step, as shown in FIG. 9, the GaAs layer 14, the AlN buffer layer 15, the GaN layer 16, and the diffused layer 19 are bonded to the substrate 18.

In the next step, as shown in FIG. 10, the GaAs layer 14, the AlN buffer layer 15, the GaN layer 16, and the diffused layer 19 are etched and separated into individual light emitting elements.

In the next step, as shown in FIG. 11, a wiring portion 20 is formed on the diffused layer 19 of each of the light emitting elements, thereby obtaining the LED array.

FIG. 12 is a schematic perspective view showing an LED-drive IC (Integrated Circuit) combination chip according to the first embodiment of the present invention.

As shown in FIG. 12, in the LED-drive IC (Integrated Circuit) combination chip, the LED array shown in FIG. 11 is arranged on one side thereof, and an integrated circuit 21 is arranged on the other side thereof. Further, the integrated circuit 21 contains a plurality of drive integrated circuits 22.

In the embodiment, the drive integrated circuits 22 are connected to the light emitting elements through the wiring portions 20, so that the drive integrated circuits 22 drive the light emitting elements to emit light.

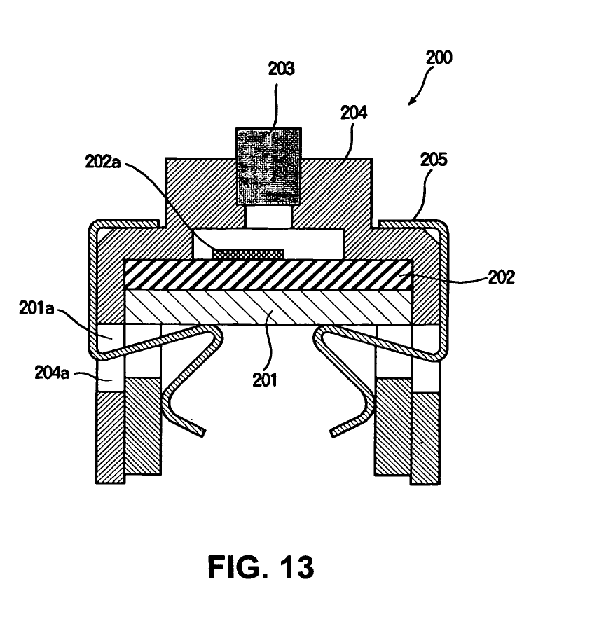

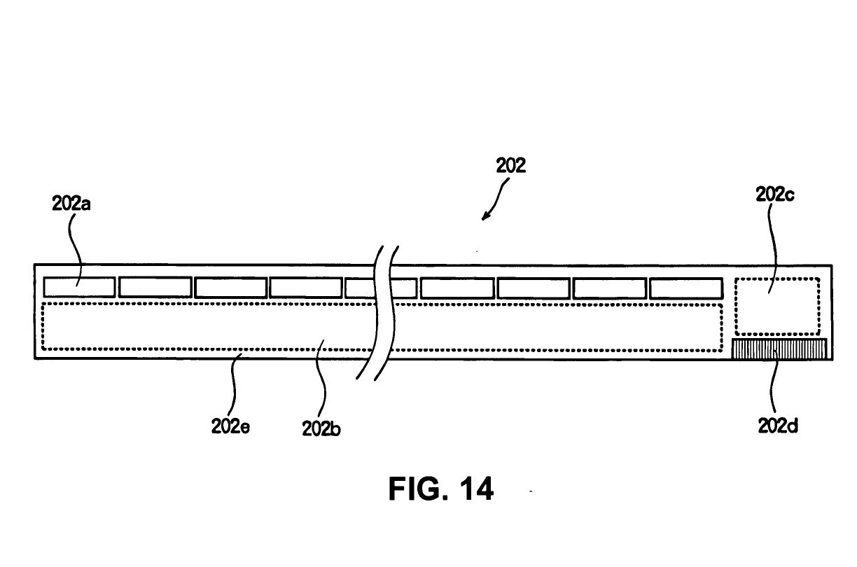

FIG. 13 is a schematic sectional view an LED print head 200 formed of the semiconductor device according to the first embodiment of the present invention. FIG. 14 is a schematic plan view showing an LED unit in the LED print head 200 shown in FIG. 13 according to the first embodiment of the present invention.

As shown in FIG. 13, an LED unit 202 is mounted on a base member 201. As shown in FIG. 14, in the LED unit 202, a plurality of the semiconductor devices is arranged on a mounting substrate 202e as light emitting units 202a along a longitudinal direction. In each of the semiconductor devices, the light emitting element in one block and the drive integrated circuit are combined. On the mounting substrate 202e, there are disposed electrical device mounting areas 202b and 202c for mounting electrical devices and wiring patterns, and a connector 202d for supplying a control signal and power from outside.

In the embodiment, a rod lens array 203 is disposed on the light emitting units 202a as an optical element for conversing light emitting from the light emitting element. In the rod lens array 203, a plurality of optical lenses with a column shape is arranged along the light emitting units 202a arranged linearly. A lens holder 204 as an optical element holder holds the rod lens array 203 at a specific position.

As shown in FIG. 13, the lens holder 204 covers the base member 201 and the LED unit 202. A clamper 205 is arranged through opening portions 201a and 204a formed in the base member 201 and the lens holder 204, so that the clamper 205 integrally holds the base member 201, the LED unit 202, and the lens holder 204. Accordingly, light emitting from the light emitting units 202a of the LED unit 202 irradiates a specific outer member through the rod lens array 203.

In the embodiment, the LED print head 200 with the configuration described above is used as an exposure device of a photoelectric printer or a photoelectric copier. Accordingly, the LED print head 200 is formed of the LED unit 202 having the semiconductor devices with high reliability. As a result, it is possible to provide the LED print head with high reliability.

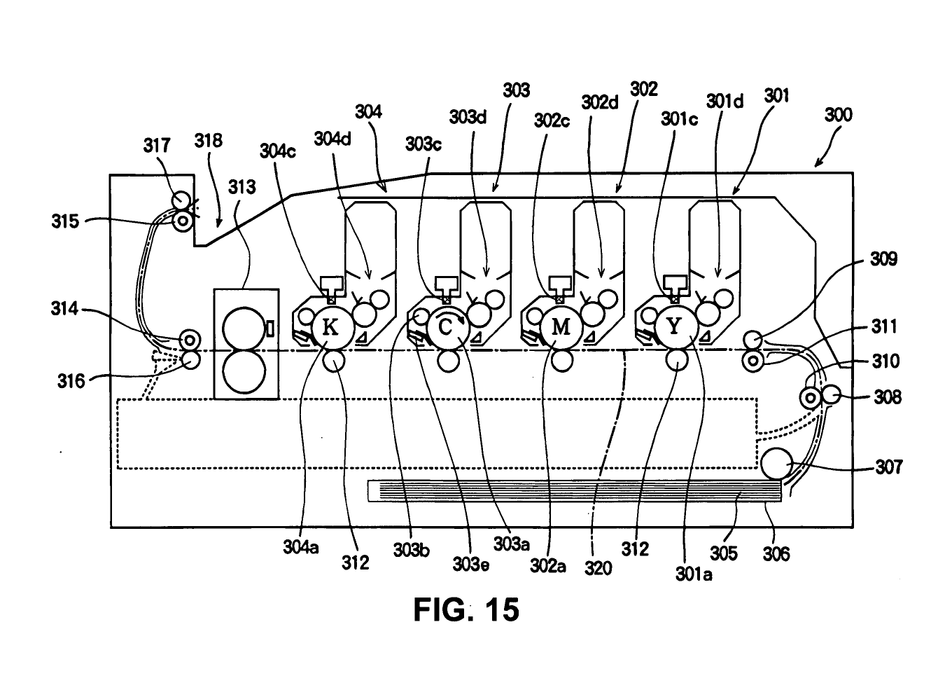

FIG. 15 is a schematic view showing an image forming apparatus 300 including the LED print head shown in FIG. 13 according to the first embodiment of the present invention. As shown in FIG. 15, in the image forming apparatus 300, four process units 301 to 304 are arranged in this order from an upstream side along a transport path 320 of a recoding medium 305 for forming images in yellow, magenta, cyan, and black, respectively. The process units 301 to 304 have an identical internal configuration, and the process unit 303 will be explained as an example.

In the process unit 303, a photosensitive drum 303a as an image supporting member is disposed to be rotatable in an arrow direction. Around the photosensitive drum 303a from an upstream side with respect to rotation of the photosensitive drum 303a, there are arranged a charging device 303b for applying a voltage and charging a surface of the photosensitive drum 303a; and an exposure device 303c for selectively irradiating light on the surface of the photosensitive drum 303a thus charged to form a static latent image thereon.

Further, there are arranged a developing device 303d for attaching toner of a specific color (cyan) to the surface of the photosensitive drum 303a with the latent image formed thereon to visualize (develop) the static latent image; and a cleaning device 303e for removing toner remaining on the surface of the photosensitive drum 303a. Note that the photosensitive drum 303a, the charging device 303b, the exposure device 303c, the developing device 303d, and the cleaning device 303e are driven with a drive source and a gear (not shown).

In the embodiment, the image forming apparatus 300 is provided with a sheet cassette 306 at a lower portion thereof for storing the recording medium 305 in a stacked state, and a hopping roller 307 above the sheet cassette 307 for separating and transporting the recording medium 305 one by one. On a downstream side of the hopping roller 307 in a direction that the recording medium 305 is transported, pinch rollers 308 and 309 and register rollers 310 and 311 are disposed for sandwiching the recording medium 305 to correct skew of the recording medium 305 and transporting the recording medium 305 to the process units 301 to 304. Note that the hopping roller 307 and the register rollers 310 and 311 are driven with a drive source and a gear (not shown).

In the process units 301 to 304, transfer rollers 312 formed of a semi-conductive rubber and the likes are disposed at positions facing the photosensitive drums 301a to 304a. It is arranged such that a specific potential is generated between the surfaces of the photosensitive drums 301a to 304a and the transfer rollers 312, so that toner on the photosensitive drums 301a to 304a is attached to the recording medium 305.

In the embodiment, a fixing device 313 includes a heating roller and a back-up roller, so that toner transferred to the recording medium 305 is heated and pressed for fixing. Discharge roller 314 and 315 sandwich the recording medium 305 discharged from the fixing device 313 with pinch rollers 316 and 317, so that the recording medium 305 is transported to a recording medium stacker portion 318. Note that the discharge roller 314 and 315 are driven with a drive source and a gear (not shown). The LED print head 200 is disposed in the exposure device 303c.

An operation of the image forming apparatus 300 will be explained next. First, the hopping roller 307 separates and transports the recording medium 305 stored in the sheet cassette 306 in a stacked state. The register rollers 310 and 311 and the pinch rollers 308 and 309 sandwich the recording medium 315, thereby transporting the recording medium 315 to the photosensitive drum 301a and the transfer roller 312. Then, the photosensitive drum 301a and the transfer roller 312 sandwich the recording medium 305 to transfer a toner image to the recording medium 305, while the photosensitive drum 301a rotates to transport the recording medium 305.

Similar to the process described above, the recording medium 305 sequentially passes through the process units 302 to 304. Accordingly, the developing devices 301d to 304d develop the latent images formed with the exposure devices 301c to 304c to form the toner images in colors, and the toner images are sequentially transferred and overlapped on the recording medium 305.

After the toner images are overlapped on the recording medium 305, the fixing device 313 fixes the toner images. Afterward, the discharge rollers 314 and 315 and the pinch rollers 316 and 317 sandwich the recording medium 305 to discharge to the recording medium stacker portion 318 outside the image forming apparatus 300. Through the process described above, a color image is formed on the recording medium 305.

### Second Embodiment

A second embodiment of the present invention will be explained next. Components in the second embodiment similar to the components in the first embodiment are designated with the same reference numerals, and explanations thereof are omitted. Explanations of operations and effects in the second embodiment similar to those in the first embodiment are omitted as well.

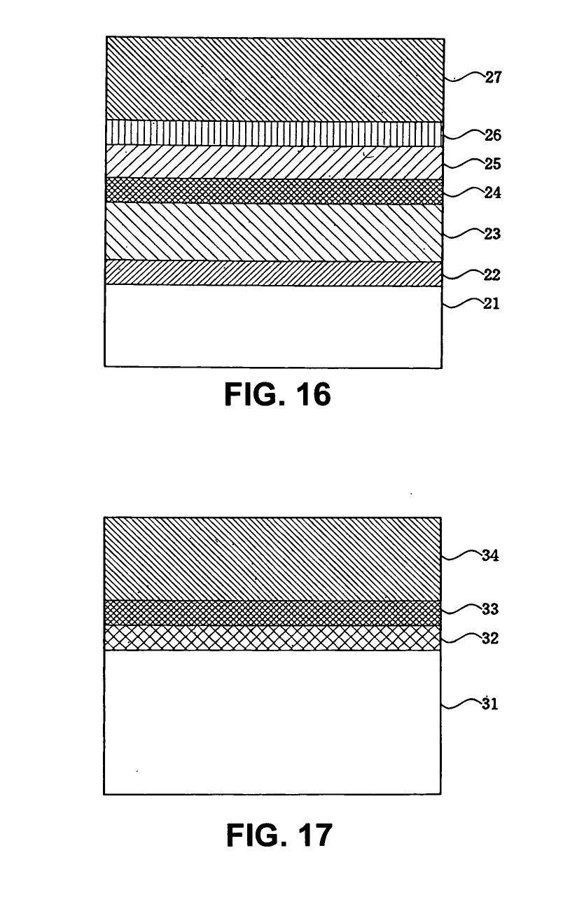

FIG. 16 is a schematic sectional view showing a laminated structure of a nitride semiconductor wafer according to the second embodiment of the present invention.

In the second embodiment, instead of the GaAs substrate 11 in the first embodiment, a silicon (Si) substrate 21 is used as a non-transparent substrate of the nitride semiconductor wafer.

As shown in FIG. 16, a GaAs buffer layer 22; a GaAs layer 23; an AlAs layer 24; a GaAs layer 25; an AlN buffer layer 26; and a GaN layer 27 are formed on the Si substrate 21.

In the embodiment, the GaAs buffer layer 22 is formed at a low temperature of, for example, 400° C. to 500° C. Afterward, the GaAs layer 23 is formed at a growth temperature of, for example, 650° C. to 700° C. Then, the GaAs layer 23, the AlAs layer 24, and the GaAs layer 25 are grown at a temperature of, for example, 650° C. to 700° C. The AlN buffer layer 26 and the GaN layer 27 are grown with a method similar to that in the first embodiment.

In the embodiment, the GaAs buffer layer 22 functions as a buffer layer for improving crystallinity of the GaAs layer 23 and the layers thereabove. Similar to the AlAs layer 13 in the first embodiment, the AlAs layer 24 is selectively etched with respect to the GaAs layer 25, the buffer layer 26, and the GaN layer 27. Accordingly, the GaAs layer 25, the buffer layer 26, and the GaN layer 27 are selectively exfoliated.

When the AlAs layer 24 is selectively etched, the GaAs layer 25, the buffer layer 26, and the GaN layer 27 are selectively exfoliated and separated from the Si substrate 21, thereby obtaining a semiconductor thin film layer.

As described above, in the second embodiment, instead of the GaAs substrate 11, the Si substrate 21 is used. Accordingly, in addition to the effect in the first embodiment, it is possible to reduce a cost of the non-transparent substrate of the nitride semiconductor wafer. It is possible to modify the second embodiment in a similar manner to the first embodiment.

### Third Embodiment

A third embodiment of the present invention will be explained next. Components in the third embodiment similar to the components in the first and second embodiments are designated with the same reference numerals, and explanations thereof are omitted. Explanations of operations and effects in the third embodiment similar to those in the first and second embodiments are omitted as well.

FIG. 17 is a schematic sectional view showing a laminated structure of a nitride semiconductor wafer according to the third embodiment of the present invention.

In the third embodiment, instead of the AlAs layer 13 in the first embodiment or the AlAs layer 24 in the second embodiment, a SiN layer 32 is used as a silicon nitride layer. Further, a substrate 31 may include a silicon (Si) substrate, a GaAs substrate, and the likes.

As shown in FIG. 17, the SiN layer 32; an AlN buffer layer 33; and a GaN layer 34 are formed on the substrate 31. The AlN buffer layer 33 is formed at a low temperature of, for example, 400° C. The GaN layer 34 is grown at a temperature of, for example, 800° C. to 1,100° C.

In the embodiment, the AlN buffer layer 33 functions as a buffer layer for improving crystallinity of the GaN layer 34. The SiN layer 32 is selectively etched with respect to the AlN buffer layer 33 and the GaN layer 34. Accordingly, the AlN buffer layer 33 and the GaN layer 34 are selectively exfoliated and separated from the substrate 31, thereby obtaining a semiconductor thin film layer.

In the embodiment, after the AlN buffer layer 33 and the GaN layer 34 are grown as epitaxial layers to obtain the nitride semiconductor wafer, the nitride semiconductor wafer may be placed in hydrofluoric acid gas, so that the SiN layer 32 as a exfoliation layer is selectively etched. When the SiN layer 32 is selectively etched, it is possible to form an upper layer in an island pattern, so that the SiN layer 32 is exposed.

As described above, in the third embodiment, the SiN layer 32 is used. Accordingly, in addition to the effects in the first and second embodiments, it is possible to properly grow the semiconductor layer closer to a lattice constant of AlN of the AlN buffer layer 34. It is possible to modify the third embodiment in a similar manner to the first or second embodiment.

Modified examples of the third embodiment of the present invention will be explained next.

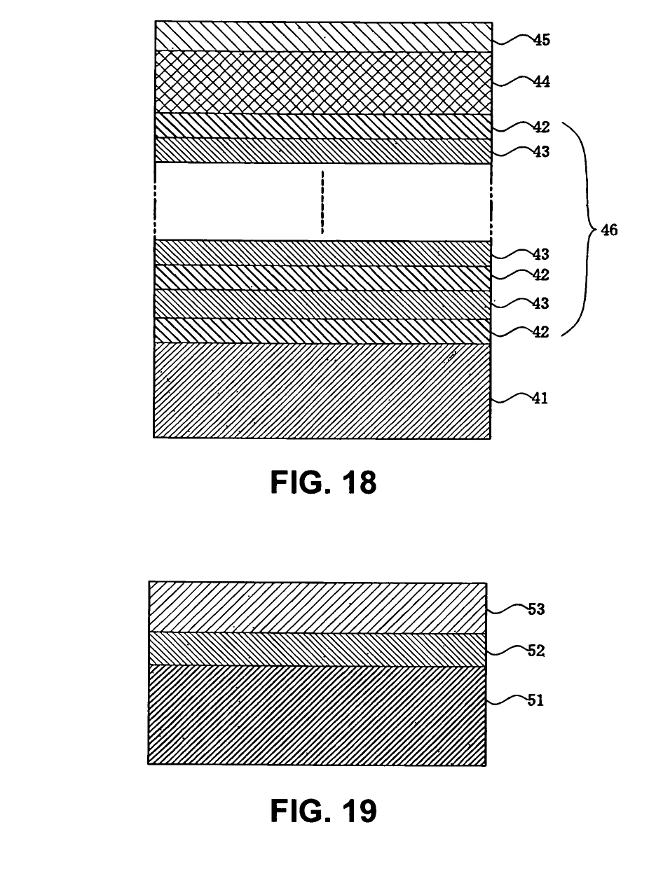

FIG. 18 is a schematic sectional view showing a first modified example of the laminated structure of the nitride semiconductor wafer according to the third embodiment of the present invention. FIG. 19 is a schematic sectional view showing a second modified example of the laminated structure of the nitride semiconductor wafer according to the third embodiment of the present invention.

In the third embodiment, the GaN layer 34 may be replaced with a light emitting element such as a light emitting diode or an electrical device such as an HEMT element. This modification is applicable to the first and second embodiments.

When the GaN layer 34 is replaced with a light emitting diode, a layered structure shown in FIG. 18 is obtained. In the layered structure, an n-type GaN layer 41 and a GaN/GaInN multiple quantum well layer 46 are laminated. The GaN/GaInN multiple quantum well layer 46 is formed of a laminated structure of a plurality of GaN layers 42 and GaInN layers 43. Further, a p-type AlGaN layer 44 and a p-type GaN layer are laminated in the layered structure.

When the GaN layer 34 is replaced with an electrical device, a layered structure shown in FIG. 19 is obtained. In the layered structure, an undoped GaN layer 51, an undoped AlGaN layer 52, and an n-type AlGaN layer 53 are laminated.

In the embodiment, the Si substrate 31 is formed of the GaAs substrate and the likes, and may be formed of an oxide substrate made of sapphire other than the Si substrate, the GaAs substrate, and the likes.

### Fourth Embodiment

A fourth embodiment of the present invention will be explained next. Components in the fourth embodiment similar to the components in the first to third embodiments are designated with the same reference numerals, and explanations thereof are omitted. Explanations of operations and effects in the fourth embodiment similar to those in the first to third embodiments are omitted as well.

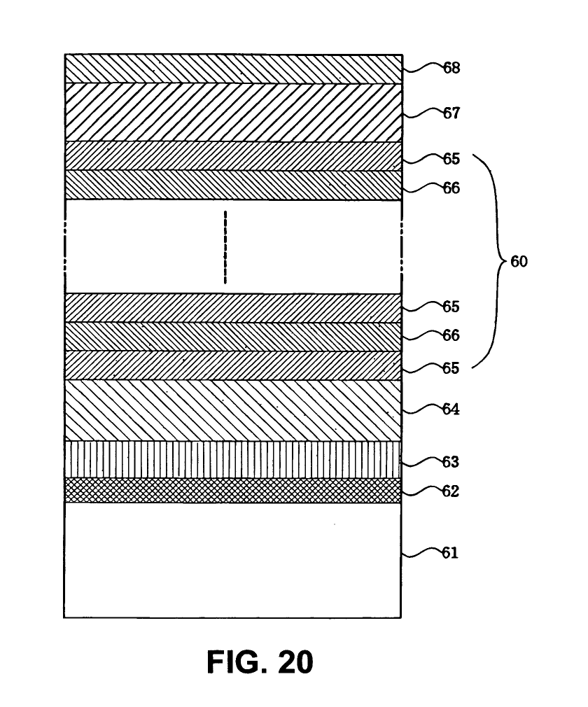

FIG. 20 is a schematic sectional view showing a laminated structure of a nitride semiconductor wafer according to the fourth embodiment of the present invention.

In the fourth embodiment, a sapphire substrate 61 is used as a substrate of the nitride semiconductor wafer. A Si layer 62 is formed on the sapphire substrate 61 as a sacrifice layer. The Si layer 62 has a thickness of, for example, 5 nm to 1 μm.

As shown in FIG. 20, an AlN buffer layer 63; and a first conductive type GaN layer 64 are formed on the Si layer 62. Further, a multiple quantum well layer 60 is formed on the first conductive type GaN layer 64. The multiple quantum well layer 60 has a laminated structure formed of a plurality of InₓGa₁₋ₓAs layers 65 and GaN layers 66. Further, a second conductive type Al_{y}Ga_{1-y}N layer 67 and a second conductive side contact layer 68 are formed on the multiple quantum well layer 60.

A method of producing the thin film semiconductor device through exfoliating the semiconductor layer from the sapphire substrate 61 will be explained next.

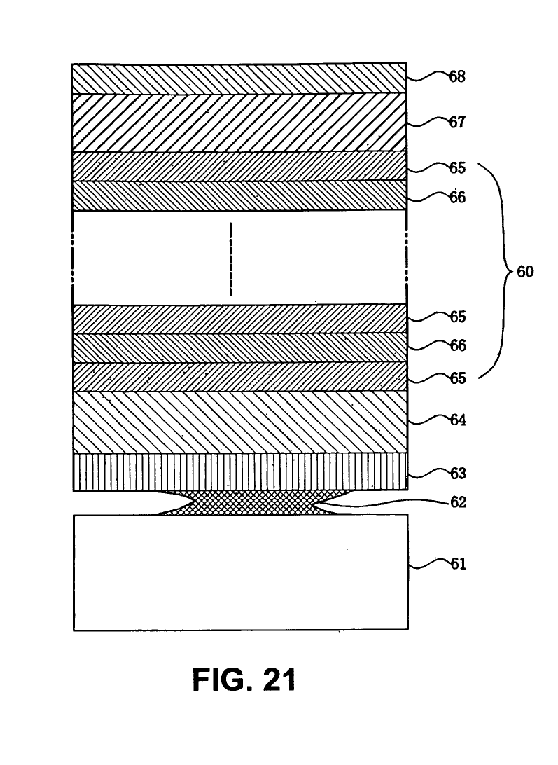

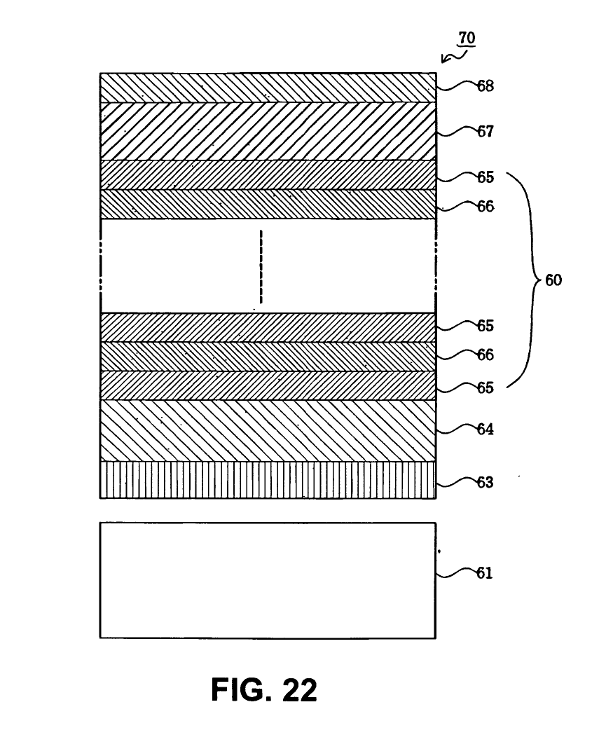

FIG. 21 is a schematic view No. 1 showing a process of producing a thin film semiconductor device according to the fourth embodiment of the present invention. FIG. 22 is a schematic view No. 2 showing the process of producing the thin film semiconductor device according to the fourth embodiment of the present invention.

As shown in FIG. 21, it is possible to selectively etch the Si layer 62 as the sacrifice layer using an acid such as hydrofluoric acid, or alkali such as potassium hydrate aqueous solution and tetra-methyl ammonium hydrate aqueous solution as the exfoliation etchant.

As shown in FIG. 22, when the Si layer 62 is selectively etched and removed, the layers above the AlN buffer layer 63 are exfoliated and separated from the sapphire substrate 61 to obtain a semiconductor thin film layer 70.

In the embodiment, the semiconductor thin film layer 70 including the semiconductor layer formed of the nitride semiconductor material is formed on the sapphire substrate 61 with the Si layer 61 as the exfoliation layer inbetween. Accordingly, in addition to the effects in the first to third embodiments, it is possible to obtain the following effects.

That is, the Si layer 61 below the semiconductor thin film layer 70 has a small thickness. Accordingly, it is possible to reduce a stress applied to the semiconductor thin film layer 70 due to a difference in thermal expansion between the semiconductor thin film layer 70 and the Si layer 61. As a result, it is possible to prevent the semiconductor thin film layer 70 from cracking, thereby obtaining the semiconductor thin film layer 70 without a defect.

In the embodiment, the sapphire substrate 61 is used as the substrate. Alternatively, an AlN substrate, a ZnO substrate, an SiC substrate, and the likes may be used as the substrate.

The disclosure of Japanese Patent Application No. 2007-068270, filed on Mar. 16, 2007, is incorporated in the application by reference.

While the invention has been explained with reference to the specific embodiments of the invention, the explanation is illustrative and the invention is limited only by the appended claims.

What is claimed is:

1. A nitride semiconductor wafer comprising:
a substrate;
a nitride semiconductor layer formed on the substrate, said nitride semiconductor layer being formed of a nitride compound in a group III to a group V; and
an AlₓGa₁₋ₓAs layer (x≧0.6) formed between the substrate and the nitride semiconductor layer.

2. The nitride semiconductor wafer according to claim 1, further comprising a GaAs layer contacting with the AlₓGa₁₋ₓAs layer.

3. The nitride semiconductor wafer according to claim 1, wherein said substrate is formed of GaAs.

4. The nitride semiconductor wafer according to claim 1, wherein said substrate is formed of silicon (Si).

5. The nitride semiconductor wafer according to claim 4, further comprising a layer contacting with the substrate, said layer being formed of a material other than GaAs.

6. A nitride semiconductor wafer comprising:
a substrate;
a nitride semiconductor layer formed on the substrate, said nitride semiconductor layer being formed of a nitride compound in a group III to a group V; and
an SiN layer formed between the substrate and the nitride semiconductor layer.

7. The nitride semiconductor wafer according to claim 6, wherein said substrate is formed of silicon (Si).

8. The nitride semiconductor wafer according to claim 1, wherein said substrate is formed of an oxide material.

9. The nitride semiconductor wafer according to claim 1, wherein said substrate is formed of an oxide material.

10. A nitride semiconductor wafer comprising:
a substrate;
a nitride semiconductor layer formed on the substrate, said nitride semiconductor layer being formed of a nitride compound in a group III to a group V; and
an Si layer formed between the substrate and the nitride semiconductor layer.

11. The nitride semiconductor wafer according to claim 10, wherein said substrate is formed of at least one of sapphire, aluminum nitride, and zinc oxide.

12. The semiconductor device comprising the nitride semiconductor wafer according to claim 1.

13. A light emitting diode print head comprising the semiconductor device according to claim 12; a drive circuit for selectively driving the semiconductor device; and a holding member for holding the semiconductor device and the drive circuit.

14. An image forming apparatus comprising a photosensitive member; a charging device for charging a surface of the photosensitive member; the light emitting diode print head according to claim 13 for selectively exposing the surface of the photosensitive member to form a static latent image; and a developing device for developing the static latent image.

15. A method of producing a semiconductor device, comprising steps of:
preparing the nitride semiconductor wafer according to claim 1; and
etching the AlₓGa₁₋ₓAs layer to exfoliate the nitride semiconductor layer from the substrate.

16. A method of producing a semiconductor device, comprising steps of:
preparing the nitride semiconductor wafer according to claim 6; and
etching the SiN layer to exfoliate the nitride semiconductor layer from the substrate.

17. A method of producing a semiconductor device, comprising steps of:
preparing the nitride semiconductor wafer according to claim 10; and
etching the Si layer to exfoliate the nitride semiconductor layer from the substrate.
